(19) United States
(12) Patent Application Publication
(10) Pub. No.: US 2026/0090455 A1
(43) Pub. Date: Mar. 26, 2026

(54) SEMICONDUCTOR PACKAGE

(71) Applicant: Samsung Electronics Co., Ltd., Suwon-si (KR)

(72) Inventor: Jongwan Seo, Suwon-si (KR)

(21) Appl. No.: 19/295,753

(22) Filed: Aug. 11, 2025

(30) Foreign Application Priority Data
Sep. 24, 2024 (KR) 10-2024-0129433

(51) Int. Cl. H01L 23/31; H01L 23/00; H01L 23/29; H01L 23/538; H01L 25/065

(52) U.S. Cl. CPC H10W 74/121; H10W 42/121; H10W 70/611; H10W 74/43; H10W 90/00; H10W 90/401; H10W 74/15; H10W 90/724; H10W 90/734

(57) ABSTRACT

The technical idea of the inventive concept provides a semiconductor package including a first package substrate, a second package substrate on the first package substrate, a plurality of semiconductor chips on the second package substrate, a molding member on the second package substrate and configured to surround the plurality of semiconductor chips, and a gas barrier layer on the molding member.

### CROSS-REFERENCE TO RELATED APPLICATION

This application is based on and claims priority under 35 U.S.C. § 119 to Korean Patent Application No. 10-2024-0129433, filed on Sep. 24, 2024, in the Korean Intellectual Property Office, the disclosure of which is incorporated by reference herein in its entirety.

### BACKGROUND

The inventive concept relates to a semiconductor package, and particularly, to a semiconductor package including a plurality of semiconductor chips.

Along with the rapid development of the electronics industry and demands of users, electronic devices have become increasingly miniaturized and more lightweight. In accordance with the miniaturization and weight reduction of electronic devices, semiconductor packages used therein also have been increasingly miniaturized and more lightweight, and semiconductor devices require high integration. Accordingly, semiconductor packages each including a plurality of semiconductor chips to provide multiple functions have been developed.

### SUMMARY

The inventive concept provides a semiconductor package with improved reliability by reducing a decrease in an adhesive force and the occurrence of delamination due to moisture.

In addition, the problems to be solved by the technical idea of the inventive concept are not limited to the problem mentioned above, and other problems could be clearly understood by those of ordinary skill in the art from the description below.

According to an aspect of the inventive concept, there is provided a semiconductor package including a first package substrate, a second package substrate on the first package substrate, a plurality of semiconductor chips on the second package substrate, a molding member on the second package substrate and configured to surround the plurality of semiconductor chips, and a gas barrier layer on the molding member.

According to another aspect of the inventive concept, there is provided a semiconductor package including a first package substrate, a second package substrate on the first package substrate and electrically connected to the first package substrate via substrate connection terminals, a substrate under-fill material layer between the second package substrate and the first package substrate and configured to surround the substrate connection terminals, a plurality of semiconductor chips horizontally spaced apart from each other on the second package substrate, a molding member on the second package substrate and configured to surround the plurality of semiconductor chips, a gas barrier layer including a first portion configured to cover an upper surface of the molding member and upper surfaces of the plurality of semiconductor chips, a second portion configured to cover a side surface of the molding member, a side surface of the second package substrate, and a side surface of the substrate under-fill material layer, and a third portion configured to cover an upper surface of the first package substrate, wherein the upper surface of the first package substrate does not vertically overlap the second package substrate, and a stiffener configured to extend in a vertical direction of the first package substrate along an edge of the first package substrate and formed on the third portion of the gas barrier layer.

According to another aspect of the inventive concept, there is provided a semiconductor package including a package substrate, at least one semiconductor chip on the package substrate, a molding member on the package substrate and configured to surround the at least one semiconductor chip, and a gas barrier layer between the package substrate and the molding member and between the at least one semiconductor chip and the molding member.

### BRIEF DESCRIPTION OF THE DRAWINGS

Embodiments of the inventive concept will be more clearly understood from the following detailed description taken in conjunction with the accompanying drawings in which:

FIG. 1 is a cross-sectional view schematically illustrating a semiconductor package according to some embodiments;

FIG. 2 is a cross-sectional view schematically illustrating a semiconductor package according to some embodiments;

FIG. 3 is a cross-sectional view schematically illustrating a semiconductor package according to some embodiments;

FIG. 4 is a cross-sectional view schematically illustrating a semiconductor package according to some embodiments;

FIG. 5 is a cross-sectional view schematically illustrating a semiconductor package according to some embodiments;

FIG. 6 is a cross-sectional view schematically illustrating a semiconductor package according to some embodiments;

FIG. 7 is a cross-sectional view schematically illustrating a semiconductor package according to some embodiments;

FIG. 8 is a cross-sectional view schematically illustrating a semiconductor package according to some embodiments;

FIG. 9 is a cross-sectional view schematically illustrating a semiconductor package according to some embodiments;

FIG. 10 is a cross-sectional view schematically illustrating a semiconductor package according to some embodiments; and

FIGS. 11 to 17 are cross-sectional views schematically illustrating, in a process order, a method of manufacturing a semiconductor package, according to some embodiments.

### DETAILED DESCRIPTION

Hereinafter, embodiments are described in detail with reference to the accompanying drawings. Like reference numerals in the drawings denote like elements, and thus their repetitive description will be omitted. As those skilled in the art would realize, the described embodiments may be modified in various different ways, all without departing from the spirit or scope of the present disclosure.

To clearly describe the present disclosure, description of some conventional elements or parts are omitted, and like numerals refer to like or similar components throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Likewise, when components are “immediately” adjacent to one another, no intervening components may be present. Further, in the specification, the word “on” or “above” may include on or below the object portion, and does not necessarily mean positioned on the upper side of the object portion based on a gravitational direction.

The terms “first,” “second,” etc., may be used herein merely to distinguish one component, layer, direction, etc. from another. In addition, unless explicitly described to the contrary, the word “comprise” and variations such as “comprises” or “comprising” will be understood to imply the inclusion of stated elements but not the exclusion of any other elements. The term “and/or” includes any and all combinations of one or more of the associated listed items. The term “connected” may be used herein to refer to a physical and/or electrical connection.

Further, throughout the specification, the phrase “in a plan view” means when an object portion is viewed from above, and the phrase “in a cross-sectional view” means when a cross-section taken by vertically cutting an object portion is viewed from the side.

Spatially relative terms, such as “under,” “below,” “lower,” “over,” “upper”, etc., may be used herein for ease of description to describe one element or relationship of structures to another element or structure as illustrated in the drawings.

The terms “surround” or “cover” or “fill” as may be used herein may not require completely surrounding or covering or filling the described elements or layers, but may, for example, refer to partially surrounding or covering or filling the described elements or layers, for example, with one or more discontinuities therein.

A first element that “covers” a second element may or may not be in contact with the second element.

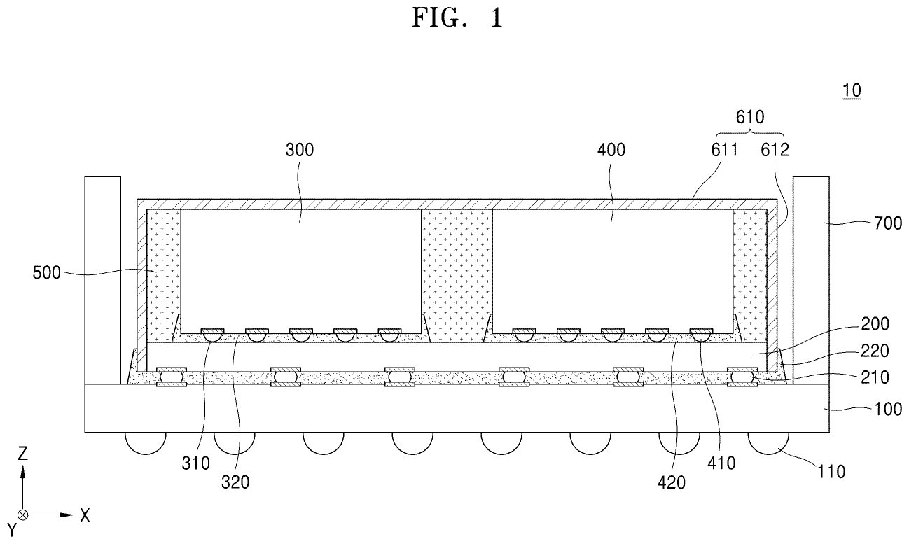

FIG. 1 is a cross-sectional view schematically illustrating a semiconductor package 10 according to some embodiments.

Referring to FIG. 1, the semiconductor package 10 may include a first package substrate 100, a second package substrate 200, a first semiconductor chip 300, a second semiconductor chip 400, a molding member 500, a gas barrier layer 610, and a stiffener 700.

Hereinafter, unless specially defined, a direction parallel to the upper surface of the first package substrate 100 and parallel to the plane of the cross sectional cut shown in FIG. 1 is defined as a first horizontal direction (the X direction), a direction perpendicular to the upper surface of the first package substrate 100 is defined as the vertical direction (the Z direction), and a direction perpendicular to the first horizontal direction (the X direction) and the vertical direction (the Z direction) is defined as a second horizontal direction (the Y direction).

The first package substrate 100 of the semiconductor package 10 is a substrate on which the second package substrate 200, the first semiconductor chip 300, the second semiconductor chip 400, and the like are mounted. The first package substrate 100 may be electrically connected to the first semiconductor chip 300 and the second semiconductor chip 400 via the second package substrate 200.

In some embodiments, the first package substrate 100 may be a printed circuit board (PCB) including a core insulating layer including at least one material selected from among a phenol resin, an epoxy resin, and polyimide. However, the first package substrate 100 is not limited thereto and may be formed based on a ceramic substrate or an organic substrate.

External connection terminals 110 may be on the lower surface of the first package substrate 100 and electrically connected to the first package substrate 100 via substrate pads (Not Shown) formed on or in the lower surface of the first package substrate 100.

Particularly, the external connection terminals 110 may be electrically connected to wirings formed inside the first package substrate 100 via substrate pads (Not Shown) attached to or within the lower surface of the first package substrate 100. Because the external connection terminals 110 are located beneath the first package substrate 100, the upper surfaces of the external connection terminals 110 may be in physical contact with the substrate pads (Not Shown) attached to or within the lower surface of the first package substrate 100. The external connection terminals 110 may be electrically connected to an external device.

The external connection terminals 110 may be formed of a solder ball. However, according to some embodiments, the external connection terminals 110 may have a structure including a pillar and solder. An external connection terminal 110 may include at least one of copper (Cu), silver (Ag), gold (Au), and tin (Sb).

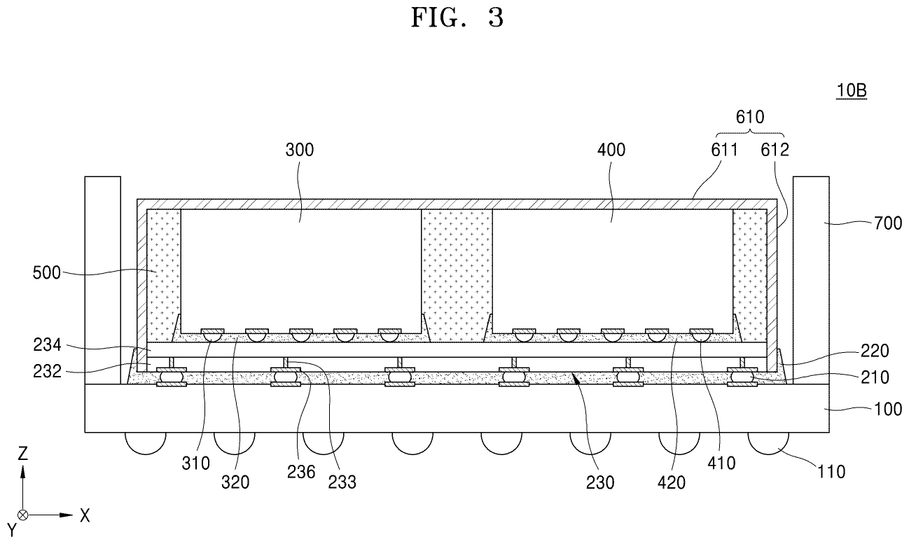

The second package substrate 200 of the semiconductor package 10 may be on the first package substrate 100. The first semiconductor chip 300 and the second semiconductor chip 400 may be on the second package substrate 200. The second package substrate 200 may electrically connect the first semiconductor chip 300 to the second semiconductor chip 400. In addition, the second package substrate 200 may electrically connect the first semiconductor chip 300 and the second semiconductor chip 400 to the first package substrate 100. In some embodiments, the second package substrate 200 may be a silicon interposer including a through silicon via (TSV). In addition, in some embodiments, the second package substrate 200 may include a silicon bridge electrically connecting the first semiconductor chip 300 to the second semiconductor chip 400. Embodiments of the second package substrate 200 are described with reference to FIGS. 3 to 5.

Substrate connection terminals 210 may be on the lower surface of the second package substrate 200 and electrically connected to the second package substrate 200 via pads formed on or in the lower surface of the second package substrate 200. The second package substrate 200 may be electrically connected to the first package substrate 100 via the substrate connection terminals 210. The substrate connection terminals 210 may be formed of a pillar structure, a ball structure, or a solder layer.

According to embodiments, a substrate under-fill material layer 220 surrounding the substrate connection terminals 210 may be between the second package substrate 200 and the first package substrate 100. For example, the substrate under-fill material layer 220 may be formed by any one process among a capillary under-fill process, a no-flow under-fill process, a molded under-fill process, and a non-conductive film process. The substrate under-fill material layer 220 may have a tapered shape of which the horizontal width gradually decreases in the vertical direction (the Z direction) from the first package substrate 100 to the second package substrate 200. In some embodiments, the substrate under-fill material layer 220 may be formed in a shape surrounding the lower surface and the side surfaces of the second package substrate 200. In other words, the second package substrate 200 may be on the substrate under-fill material layer 220 and the substrate under-fill material layer 220 may also partially cover the side surfaces of the second package substrate 200.

The semiconductor package 10 may include the first semiconductor chip 300 and the second semiconductor chip 400. The first semiconductor chip 300 and the second semiconductor chip 400 may be on the second package substrate 200. For example, the first semiconductor chip 300 and the second semiconductor chip 400 may be on the second package substrate 200 to be spaced apart from each other in the first horizontal direction (the X direction).

Although FIG. 1 schematically shows the first semiconductor chip 300 and the second semiconductor chip 400, each of the first semiconductor chip 300 and the second semiconductor chip 400 may include a semiconductor substrate (Not Shown) and a semiconductor device layer (Not Shown).

The semiconductor substrate (Not Shown) may include silicon (Si), e.g., monocrystalline Si, polycrystalline Si, or amorphous Si. Alternatively, the semiconductor substrate (Not Shown) may include a semiconductor element, such as germanium (Ge), or a compound semiconductor, such as silicon carbide (SiC), gallium arsenide (GaAs), indium arsenide (InAs), or indium phosphide (InP). The semiconductor substrate (Not Shown) may have a silicon on insulator (SOI) structure. For example, the semiconductor substrate (Not Shown) may include a buried oxide (BOX) layer. The semiconductor substrate (Not Shown) may include a conductive region, for example, an impurity-doped well or an impurity-doped structure. In addition, the semiconductor substrate (Not Shown) may have various device isolation structures, such as a shallow trench isolation (STI) structure.

The semiconductor device layer (Not Shown) may include a wiring pattern electrically connected to a plurality of semiconductor devices formed on the semiconductor substrate (Not Shown). The wiring pattern may include a metal wiring layer and a via plug. For example, the wiring pattern may have a multi-layer structure in which two or more metal wiring layers and two or more via plugs are alternately stacked.

The first semiconductor chip 300 may be mounted on the second package substrate 200 in a flip chip manner. The first semiconductor chip 300 may be mounted on the second package substrate 200 through a plurality of first chip connection terminals 310 such that an active surface of the first semiconductor chip 300, on which a semiconductor device is formed, faces downward. A first chip under-fill material layer 320 may be between the first semiconductor chip 300 and the second package substrate 200 and surround the plurality of first chip connection terminals 310. The first chip under-fill material layer 320 may have a tapered shape of which the horizontal width gradually increases in the vertical direction (the Z direction) from the first semiconductor chip 300 to the second package substrate 200. In some embodiments, the first chip under-fill material layer 320 may be formed in a shape surrounding the lower surface and the side surfaces of the first semiconductor chip 300. In other words, the first semiconductor chip 300 may be on the first chip under-fill material layer 320 and the first chip under-fill material layer 320 may also partially cover the side surfaces of the first semiconductor chip 300.

Likewise, the second semiconductor chip 400 may be mounted on the second package substrate 200 in the flip chip manner. The second semiconductor chip 400 may be mounted on the second package substrate 200 through a plurality of second chip connection terminals 410 such that an active surface of the second semiconductor chip 400, on which a semiconductor device is formed, faces downward. A second chip under-fill material layer 420 may be between the second semiconductor chip 400 and the second package substrate 200 and surround the plurality of second chip connection terminals 410. The second chip under-fill material layer 420 may have a tapered shape of which the horizontal width gradually increases in the vertical direction (the Z direction) from the second semiconductor chip 400 to the second package substrate 200. In some embodiments, the second chip under-fill material layer 420 may be formed in a shape surrounding the lower surface and the side surfaces of the second semiconductor chip 400. In other words, the second semiconductor chip 400 may be on the second chip under-fill material layer 420 and the second chip under-fill material layer 420 may also partially cover the side surfaces of the second semiconductor chip 400.

In some embodiments, various types of a plurality of individual devices may be on the active surfaces of the first semiconductor chip 300 and the second semiconductor chip 400. For example, the plurality of individual devices may include various microelectronics devices, e.g., a complementary metal-insulator-semiconductor (CMOS) transistor, a metal-oxide-semiconductor field effect transistor (MOSFET), a system large scale integration (LSI) chip, an image sensor, such as a CMOS imaging sensor (CIS), a micro-electro-mechanical system (MEMS), an active device, a passive device, and the like.

According to embodiments, the first semiconductor chip 300 may include a memory chip. For example, the first semiconductor chip 300 is a memory chip and may include a volatile memory chip, such as dynamic random access memory (DRAM) or static random access memory (SRAM), or a non-volatile memory chip, such as phase-change random access memory (PRAM), magnetoresistive random access memory (MRAM), ferroelectric random access memory (FeRAM), or resistive random access memory (RRAM). A plurality of memory chips may be stacked and included in the first semiconductor chip 300. For example, the first semiconductor chip 300 may be a high bandwidth memory (HBM) package or a wire-bonding memory package, in which a plurality of memory chips is stacked. However, the first semiconductor chip 300 is not limited thereto and may include a logic chip, such as a central processing unit (CPU), a graphics processing unit (GPU), a field-programmable gate array (FPGA), or an application processor (AP), such as a digital signal processor, an encryption processor, a microprocessor, or a microcontroller.

According to embodiments, the second semiconductor chip 400 may include a logic chip. For example, the second semiconductor chip 400 may include a CPU, a GPU, a FPGA, or an AP, such as a digital signal processor, an encryption processor, a microprocessor, or a microcontroller. For example, the second semiconductor chip 400 may be a logic chip, such as an analog-digital converter (ADC) or an application-specific integrated circuit (IC) (ASIC). However, the second semiconductor chip 400 is not limited thereto and may include a memory chip, such as a volatile memory chip (e.g., DRAM) or a non-volatile memory chip (e.g., read-only memory (ROM) or flash memory). The second semiconductor chip 400 may be a system on chip (SOC). In addition, the second semiconductor chip 400 may be configured by combining the logic chip, the memory chip, and the SOC.

Although FIG. 1 shows only the first semiconductor chip 300 and the second semiconductor chip 400, the semiconductor package 10 is not limited thereto and may include three or more semiconductor chips. In this case, the three or more semiconductor chips may be on the second package substrate 200 to be spaced apart from each other in at least one horizontal direction (the X direction and/or the Y direction).

Although FIG. 1 schematically shows the first semiconductor chip 300 and the second semiconductor chip 400, at least one of the first semiconductor chip 300 and the second semiconductor chip 400 may be an HBM chip including a plurality of semiconductor chips stacked in the vertical direction (the Z direction).

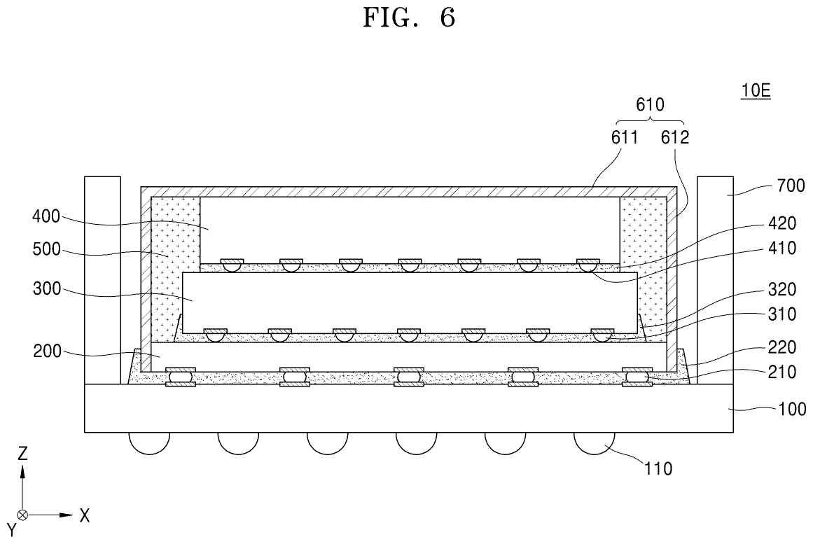

In addition, although FIG. 1 shows that the first semiconductor chip 300 and the second semiconductor chip 400 are on the second package substrate 200 to be spaced apart from each other in the first horizontal direction (the X direction), the first semiconductor chip 300 and the second semiconductor chip 400 are not limited thereto and may be stacked on the second package substrate 200 in the vertical direction (the Z direction). This is described below with reference to FIG. 6.

The molding member 500 of the semiconductor package 10 may be on the second package substrate 200 and surround the first semiconductor chip 300 and the second semiconductor chip 400. The molding member 500 may protect the first semiconductor chip 300, the second semiconductor chip 400, and the second package substrate 200 from the outside.

The molding member 500 may be formed to cover the side surfaces of each of the first semiconductor chip 300 and the second semiconductor chip 400. The molding member 500 may be formed to cover the side surfaces of the first semiconductor chip 300 and the side surfaces of the first chip under-fill material layer 320 between the first semiconductor chip 300 and the second package substrate 200. In addition, the molding member 500 may be formed to cover the side surfaces of the second semiconductor chip 400 and the side surfaces of the second chip under-fill material layer 420 between the second semiconductor chip 400 and the second package substrate 200. In embodiments where the side surfaces of the first semiconductor chip 300 are at least partially covered by the first chip under-fill material layer 320 and/or the side surfaces of the second semiconductor chip 400 are at least partially covered by the second chip under-fill material layer 420, the molding member 500 may be configured to cover the at least some of the remainder of the side surfaces of the first semiconductor chip 300 and/or the second semiconductor chip 400.

In embodiments, the molding member 500 may be formed not to cover the upper surface of the first semiconductor chip 300 and the upper surface of the second semiconductor chip 400. In this case, the upper surface of the molding member 500 may be coplanar with the upper surface of the first semiconductor chip 300 and the upper surface of the second semiconductor chip 400. However, the molding member 500 is not limited thereto, and in some embodiments, the molding member 500 may be formed to cover the upper surface of the first semiconductor chip 300 and/or the upper surface of the second semiconductor chip 400.

The molding member 500 may be formed only on the upper surface of the second package substrate 200 and formed not to cover the side surface of the second package substrate 200. The side surface of the molding member 500 may be coplanar with the side surface of the second package substrate 200.

According to embodiments, the molding member 500 may be formed of a thermosetting resin, such as an epoxy resin, a thermoplastic resin, such as polyimide, or a resin including a reinforcing material, such as an inorganic filler, particularly, of an Ajinomoto build-up film (ABF), flame retardant class 4 (FR-4), bismaleimide triazine (BT), or the like but is not limited thereto, and the molding member 500 may be formed of a molding material, such as an epoxy mold compound (EMC), or a photosensitive material, such as a photoimageable encapsulant (PIE). In some embodiments, a portion of the molding member 500 may be formed of an insulating material, such as a silicon oxide layer, a silicon nitride layer, or a silicon oxynitride layer.

The gas barrier layer 610 of the semiconductor package 10 may be on the molding member 500. According to embodiments, the gas barrier layer 610 may include a first portion 611 covering the upper surface of the molding member 500 and a second portion 612 covering the side surface of the molding member 500.

The first portion 611 of the gas barrier layer 610 may extend in the horizontal directions (the X direction and/or the Y direction) over the upper surface of the molding member 500, the upper surface of the first semiconductor chip 300, and the upper surface of the second semiconductor chip 400. Therefore, the first portion 611 may be formed to cover the upper surface of the molding member 500, the upper surface of the first semiconductor chip 300, and the upper surface of the second semiconductor chip 400.

The second portion 612 of the gas barrier layer 610 may extend over the side surface of the molding member 500 and the side surface of the second package substrate 200. For example, the second portion 612 shown in FIG. 1 (representing an X-Z plane) may be formed by extending in the vertical direction (the Z direction) and/or the second horizontal direction (the Y direction) over the side surface of the molding member 500 and the side surface of the second package substrate 200. The second portion 612 may be formed to cover the side surface of the second package substrate 200, and a portion of the second portion 612 may be covered by the substrate under-fill material layer 220.

The gas barrier layer 610 may have a characteristic that a water vapor transmission rate (WVTR) is less than 1 E-3 g/m²·day. The gas barrier layer 610 may be formed of a material having a low WVTR, thereby preventing moisture from being absorbed into the molding member 500. According to embodiments, the gas barrier layer 610 may include a ceramic layer including at least one of silicon dioxide (SiO₂), silicon nitride (SiN), silicon oxide (SiOₓ), alumina (Al₂O₃), aluminum nitride (AlN), titanium dioxide (TiO₂), zinc oxide (ZnO), and titanium nitride (TiN) or a metal layer including at least one of palladium (Pd), nickel (Ni), titanium (Ti), Cu, Au, Ag, and zinc (Zn).

The gas barrier layer 610 may be formed with a constant thickness. The thickness of the gas barrier layer 610 may satisfy the minimum thickness, which does not allow moisture to be absorbed into the gas barrier layer 610. For example, the thickness of the gas barrier layer 610 may be 5 μm or greater.

The gas barrier layer 610 may be formed by at least one process among a sputtering process, a dipping process, an ink jetting process, a chemical vapor deposition (CVD) process, and a physical vapor deposition (PVD) process. It should be understood that the word “gas” in the term “gas barrier layer” is used to refer to the potential methods used to deposit the gas barrier layer 610. In some embodiments, the gas barrier layer 610 is a solid. According to when the gas barrier layer 610 is formed in a semiconductor packaging process, the shape of the gas barrier layer 610 may vary. As described below, the semiconductor package 10 of FIG. 1 may be formed by forming the gas barrier layer 610 after a sawing process in which the second package substrate 200, on which the first semiconductor chip 300, the second semiconductor chip 400, and the molding member 500 are formed, is cut according to a size. Because the second package substrate 200 is attached to the first package substrate 100 after forming the gas barrier layer 610, a portion of the second portion 612 of the gas barrier layer 610 may be covered by the substrate under-fill material layer 220.

The stiffener 700 of the semiconductor package 10 may be formed on the first package substrate 100 to protect semiconductor chips. The stiffener 700 may be formed by extending in the vertical direction (the Z direction) along an edge of the first package substrate 100. According to embodiments, the stiffener 700 may include a metal, such as steel or Cu.

The stiffener 700 may be formed by protruding in the vertical direction (the Z direction) from the edge of the first package substrate 100, to protect the first semiconductor chip 300 and the second semiconductor chip 400 in an internal space surrounded by the stiffener 700. According to embodiments, the upper surface of the stiffener 700 may be at a higher vertical level than the upper surfaces of the first semiconductor chip 300 and the second semiconductor chip 400. In addition, according to embodiments, the upper surface of the stiffener 700 may be at a higher vertical level than the upper surface of the gas barrier layer 610.

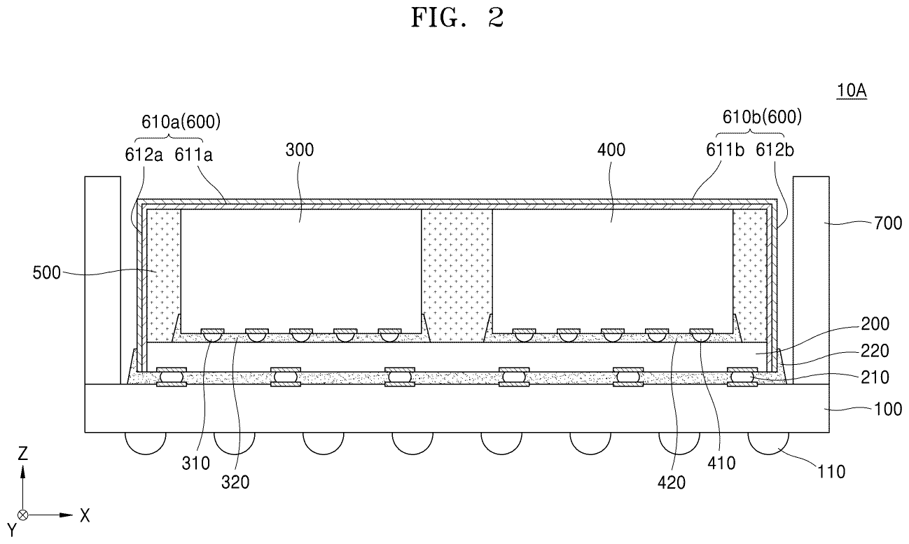

FIG. 2 is a cross-sectional view schematically illustrating a semiconductor package 10A according to some embodiments. Most components constituting the semiconductor package 10A to be described below and materials forming the components are the same as or similar to those described above with reference to FIG. 1. Therefore, for convenience of description, differences between the semiconductor package 10A of FIG. 2 and the semiconductor package 10 of FIG. 1 are mainly described.

Referring to FIG. 2, the semiconductor package 10A according to some embodiments may include the first package substrate 100, the second package substrate 200, the first semiconductor chip 300, the second semiconductor chip 400, the molding member 500, a first gas barrier layer 610a, a second gas barrier layer 610b, and the stiffener 700.

The first gas barrier layer 610a may be on the molding member 500. The first gas barrier layer 610a may include a first portion 611a covering the upper surface of the molding member 500 and a second portion 612a covering the side surface of the molding member 500. The first portion 611a may extend in the horizontal directions (the X direction and/or the Y direction) over the upper surface of the molding member 500, the upper surface of the first semiconductor chip 300, and the upper surface of the second semiconductor chip 400. Therefore, the first portion 611a may be formed to cover the upper surface of the molding member 500, the upper surface of the first semiconductor chip 300, and the upper surface of the second semiconductor chip 400. The second portion 612a may extend over the side surface of the molding member 500 and the side surface of the second package substrate 200. The second portion 612a may be formed by extending in the vertical direction (the Z direction) and/or the second horizontal direction (the Y direction) over the side surface of the molding member 500 and the side surface of the second package substrate 200.

The second gas barrier layer 610b may be on the first gas barrier layer 610a. The second gas barrier layer 610b may include a first portion 611b and a second portion 612b and have substantially the same shape as the first gas barrier layer 610a. A portion of the second portion 612b of the second gas barrier layer 610b may be covered by the substrate under-fill material layer 220.

Each of the first gas barrier layer 610a and the second gas barrier layer 610b may have a characteristic that a WVTR is less than 1 E-3 g/m²·day. The first gas barrier layer 610a and the second gas barrier layer 610b may be formed of different materials. For example, the first gas barrier layer 610a may include a ceramic layer including at least one of SiO₂, SiN, SiOₓ, Al₂O₃, AlN, TiO₂, ZnO, and TiN, and the second gas barrier layer 610b may include a metal layer including at least one of Pd, Ni, Ti, Cu, Au, Ag, and Zn. However, the first gas barrier layer 610a and the second gas barrier layer 610b are not limited thereto, the first gas barrier layer 610a may include a metal layer, and the second gas barrier layer 610b may include a ceramic layer. Alternatively, the first gas barrier layer 610a and the second gas barrier layer 610b may be ceramic layers formed of different materials or metal layers formed of different materials.

Each of the first gas barrier layer 610a and the second gas barrier layer 610b may be formed with a constant thickness. For example, each of the first gas barrier layer 610a and the second gas barrier layer 610b may have a thickness of 5 μm or greater.

Although FIG. 2 shows a dual gas barrier layer 600 including the first gas barrier layer 610a and the second gas barrier layer 610b, the semiconductor package 10A is not limited thereto and may include a plurality of gas barrier layers.

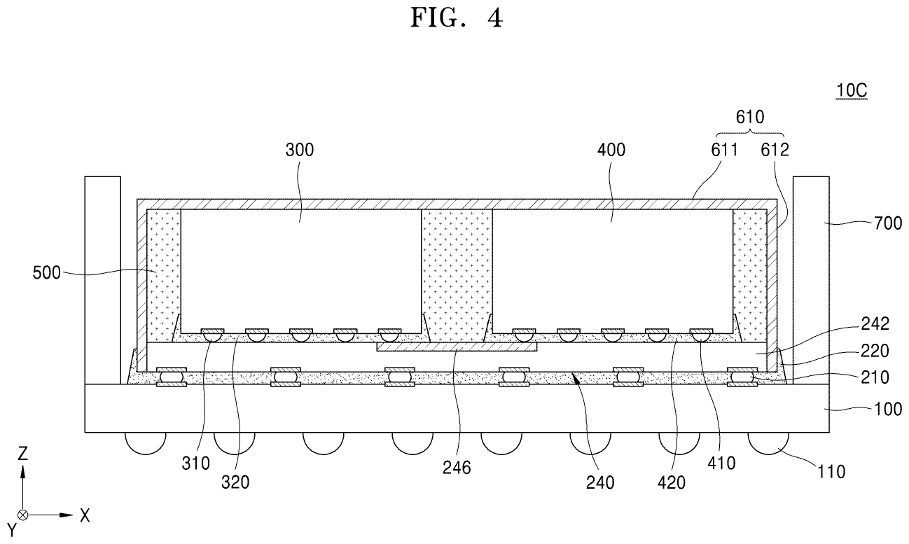

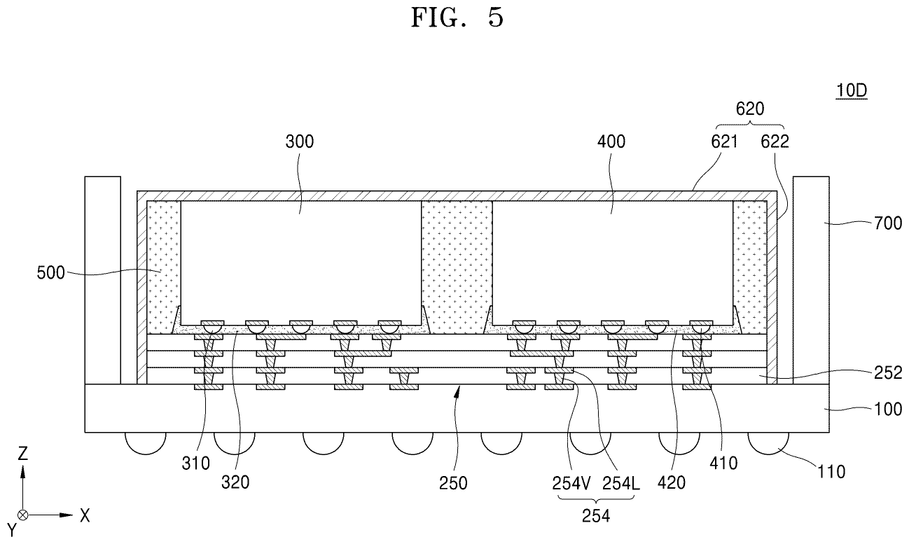

FIG. 3 is a cross-sectional view schematically illustrating a semiconductor package 10B according to some embodiments. FIG. 4 is a cross-sectional view schematically illustrating a semiconductor package 10C according to some embodiments. FIG. 5 is a cross-sectional view schematically illustrating a semiconductor package 10D according to some embodiments. Most components constituting each of the semiconductor packages 10B, 10C, and 10D to be described with reference to FIGS. 3 to 5 and materials forming the components are the same as or similar to those described above with reference to FIG. 1. Therefore, for convenience of description, differences between the semiconductor packages 10B, 10C, and 10D of FIGS. 3 to 5 and the semiconductor package 10 of FIG. 1 are mainly described.

Referring to FIG. 3, the semiconductor package 10B according to some embodiments may include the first package substrate 100, a second package substrate 230, the first semiconductor chip 300, the second semiconductor chip 400, the molding member 500, the gas barrier layer 610, and the stiffener 700.

The second package substrate 230 may be an interposer including a body layer 232 and a wiring layer 234. The semiconductor package 10B may connect the first semiconductor chip 300 in parallel to the second semiconductor chip 400 by using the interposer and connect the interposer to the first package substrate 100.

The second package substrate 230 may be formed based on Si and electrically connect the first semiconductor chip 300 to the second semiconductor chip 400. According to embodiments, the second package substrate 230 may include the body layer 232 and the wiring layer 234. The wiring layer 234 may be on the upper surface of the body layer 232. The wiring layer 234 may include a wiring pattern. The wiring pattern may electrically connect the first semiconductor chip 300 to the second semiconductor chip 400 or electrically connect between the first semiconductor chip 300 and through electrodes 233 and between the second semiconductor chip 400 and the through electrodes 233.

The through electrodes 233 may be formed inside the body layer 232. The through electrodes 233 may pass through the body layer 232 in the vertical direction (the Z direction). According to embodiments, the through electrode 233 may include a TSV. The through electrodes 233 may be electrically connected to bumps via pads 236 formed on or in the lower surface of the body layer 232, respectively.

The gas barrier layer 610 may be on the molding member 500 and include the first portion 611 covering the upper surface of the molding member 500 and the second portion 612 covering the side surface of the molding member 500. The first portion 611 of the gas barrier layer 610 may extend in the horizontal directions (the X direction and/or the Y direction) over the upper surface of the molding member 500, the upper surface of the first semiconductor chip 300, and the upper surface of the second semiconductor chip 400. The second portion 612 of the gas barrier layer 610 may extend over the side surface of the molding member 500 and the side surface of the second package substrate 230. For example, the second portion 612 of the gas barrier layer 610 may extend over the side surface of the wiring layer 234 of the second package substrate 230 and the side surface of the body layer 232 of the second package substrate 230.

Referring to FIG. 4, the semiconductor package 10C according to some embodiments may include the first package substrate 100, a second package substrate 240, the first semiconductor chip 300, the second semiconductor chip 400, the molding member 500, the gas barrier layer 610, and the stiffener 700.

The second package substrate 240 may be a redistribution substrate including a silicon bridge 246. The first semiconductor chip 300 and the second semiconductor chip 400 may each be arranged on the second package substrate 240 to at least partially overlap with the silicon bridge 246. Some of the plurality of first chip connection terminals 310 of the first semiconductor chip 300 and some of the plurality of second chip connection terminals 410 of the second semiconductor chip 400 may be in contact with the silicon bridge 246. The first semiconductor chip 300 may be electrically connected to the second semiconductor chip 400 via the silicon bridge 246.

The second package substrate 240 may be electrically connected to the first package substrate 100 via the substrate connection terminals 210, and the substrate under-fill material layer 220 surrounding the substrate connection terminals 210 may be between the second package substrate 240 and the first package substrate 100.

The gas barrier layer 610 may be on the molding member 500 and include the first portion 611 covering the upper surface of the molding member 500 and the second portion 612 covering the side surface of the molding member 500. The second portion 612 of the gas barrier layer 610 may extend over the side surface of the molding member 500 and the side surface of the second package substrate 240. A portion of the second portion 612 may be covered by the substrate under-fill material layer 220.

Referring to FIG. 5, the semiconductor package 10D according to some embodiments may include the first package substrate 100, a second package substrate 250, the first semiconductor chip 300, the second semiconductor chip 400, the molding member 500, the gas barrier layer 610, and the stiffener 700.

The second package substrate 250 may be a redistribution substrate including a redistribution insulating layer 252 and a redistribution pattern 254.

The redistribution insulating layer 252 may be formed of an insulating material, e.g., a photo imageable dielectric (PID) resin. In some embodiments, the redistribution insulating layer 252 may further include an inorganic filler. In some embodiments, the redistribution insulating layer 252 may have a multi-layer structure in which the redistribution pattern 254 is on each layer.

The redistribution pattern 254 may include a redistribution line pattern 254L extending in the horizontal direction and a redistribution via pattern 254V extending in the vertical direction (the Z direction) from the redistribution line pattern 254L. The redistribution line pattern 254L may be on at least one surface of the upper surface and the lower surface of the redistribution insulating layer 252 or inside the redistribution insulating layer 252. The redistribution via pattern 254V may be connected to a portion of the redistribution line pattern 254L by passing through the redistribution insulating layer 252.

The redistribution pattern 254 may include a conductive material, e.g., Cu, aluminum (Al), Ag, Sn, Au, Ni, lead (Pb), Ti, or an alloy thereof.

The second package substrate 250 may be on the first package substrate 100 and electrically connected to the first package substrate 100. In this case, the substrate connection terminals 210 (see FIG. 1) and the substrate under-fill material layer 220 (see FIG. 1) may be omitted, and the second package substrate 250 may be on the first package substrate 100 and electrically connect the first semiconductor chip 300, the second semiconductor chip 400, and the first package substrate 100 to each other.

The gas barrier layer 610 may be on the molding member 500 and include the first portion 611 covering the upper surface of the molding member 500 and the second portion 612 covering the side surface of the molding member 500. The second portion 612 of the gas barrier layer 610 may extend over the side surface of the molding member 500 and the side surface of the second package substrate 250.

FIG. 6 is a cross-sectional view schematically illustrating a semiconductor package 10E according to some embodiments. Hereinafter, a duplicated description of the semiconductor package 10 described with reference to FIG. 1 and the semiconductor package 10E of FIG. 6 is omitted, and differences therebetween are mainly described.

Referring to FIG. 6, the semiconductor package 10E according to some embodiments may include the first package substrate 100, the second package substrate 200, the first semiconductor chip 300, the second semiconductor chip 400, the molding member 500, the gas barrier layer 610, and the stiffener 700.

The first semiconductor chip 300 and the second semiconductor chip 400 may be vertically stacked on the second package substrate 200. The first semiconductor chip 300 and the second semiconductor chip 400 may be referred to as a lower semiconductor chip 300 and an upper semiconductor chip 400, respectively.

The lower semiconductor chip 300 may be mounted on the second package substrate 200 in the flip chip manner. The lower semiconductor chip 300 may be mounted on the second package substrate 200 through the plurality of first chip connection terminals 310 such that the active surface of the lower semiconductor chip 300, on which a semiconductor device is formed, faces downward. The first chip under-fill material layer 320 may be between the lower semiconductor chip 300 and the second package substrate 200 and surround the plurality of first chip connection terminals 310.

The lower semiconductor chip 300 may include a semiconductor substrate (Not Shown), a semiconductor device layer (Not Shown) formed beneath the semiconductor substrate (Not Shown), and through electrodes (Not Shown) vertically passing through the semiconductor substrate (Not Shown) and at least a portion of the semiconductor device layer (Not Shown). The lower semiconductor chip 300 may be electrically connected to the upper semiconductor chip 400 via the through electrodes (Not Shown).

The upper semiconductor chip 400 may be mounted on the lower semiconductor chip 300 in the flip chip manner. The upper semiconductor chip 400 may be mounted on the lower semiconductor chip 300 through the plurality of second chip connection terminals 410 such that the active surface of the upper semiconductor chip 400, on which a semiconductor device is formed, faces downward. The upper semiconductor chip 400 may be electrically connected to the through electrodes (Not Shown) of the lower semiconductor chip 300 via the plurality of second chip connection terminals 410 and connection pads (Not Shown). The second chip under-fill material layer 420 may be between the upper semiconductor chip 400 and the lower semiconductor chip 300 and surround the plurality of second chip connection terminals 410.

The molding member 500 may be on the second package substrate 200 and surround the lower semiconductor chip 300 and the upper semiconductor chip 400. The molding member 500 may be formed to cover the upper surfaces and the side surfaces of the lower semiconductor chip 300 and the upper semiconductor chip 400, the side surfaces of the first chip under-fill material layer 320 and the second chip under-fill material layer 420, and the upper surface of the second package substrate 200.

The gas barrier layer 610 may be on the molding member 500 and include the first portion 611 covering the upper surface of the molding member 500 and the second portion 612 covering the side surface of the molding member 500. The second portion 612 of the gas barrier layer 610 may extend over the side surface of the molding member 500 and the side surface of the second package substrate 250. A portion of the second portion 612 may be covered by the substrate under-fill material layer 220.

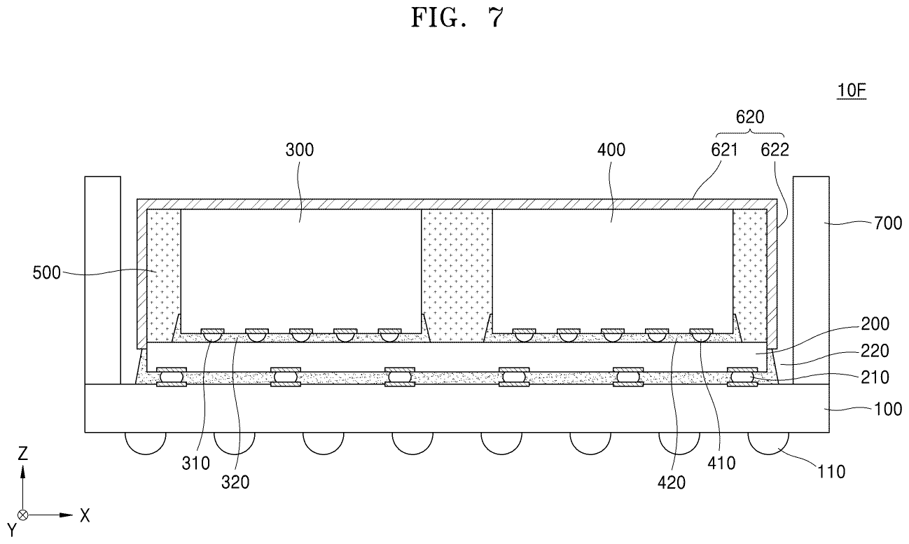

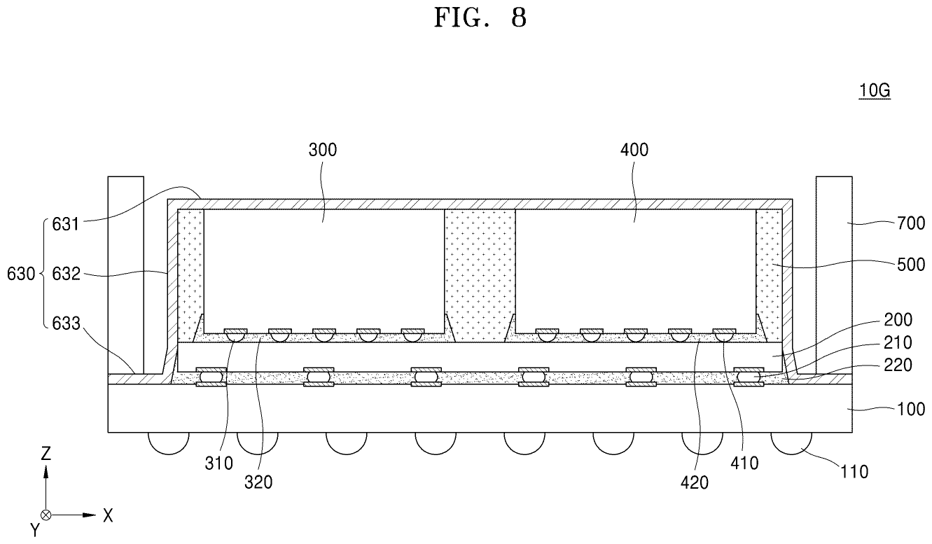

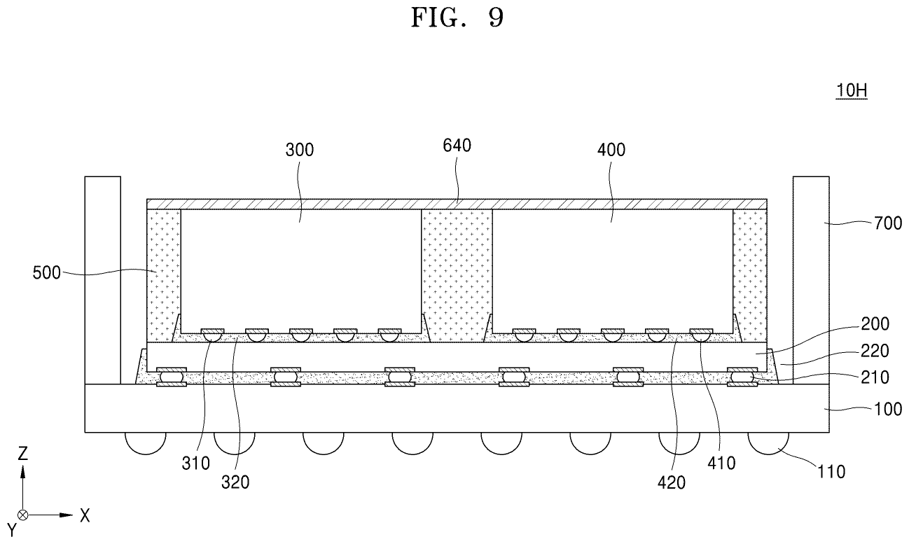

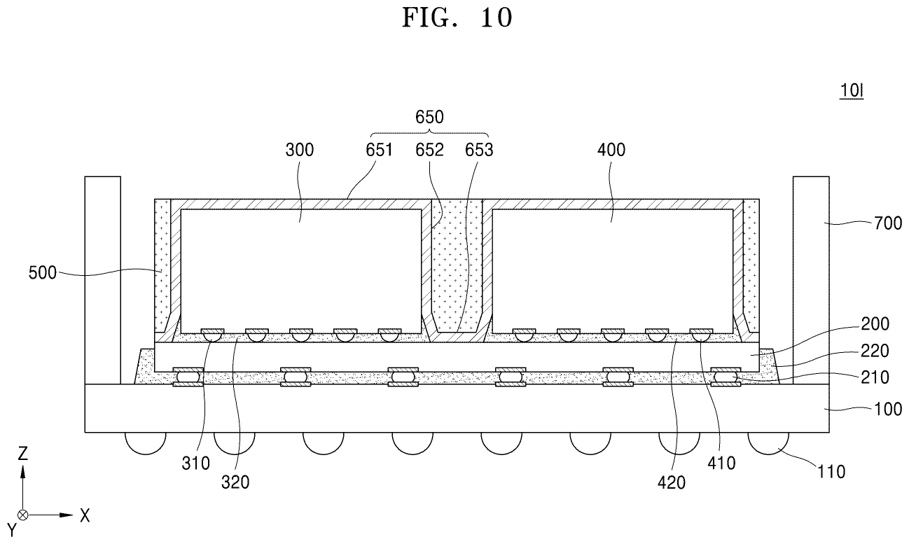

FIG. 7 is a cross-sectional view schematically illustrating a semiconductor package 10F according to some embodiments. FIG. 8 is a cross-sectional view schematically illustrating a semiconductor package 10G according to some embodiments. FIG. 9 is a cross-sectional view schematically illustrating a semiconductor package 10H according to some embodiments. FIG. 10 is a cross-sectional view schematically illustrating a semiconductor package 10I according to some embodiments.

Most components constituting each of the semiconductor packages 10F, 10G, 10H, and 10I to be described with reference to FIGS. 7 to 10 and materials forming the components are the same as or similar to those described above with reference to FIG. 1. Therefore, for convenience of description, differences between the semiconductor packages 10F, 10G, 10H, and 10I of FIGS. 7 to 10 and the semiconductor package 10 of FIG. 1 are mainly described.

Referring to FIG. 7, the semiconductor package 10F according to some embodiments may include the first package substrate 100, the second package substrate 200, the first semiconductor chip 300, the second semiconductor chip 400, the molding member 500, a gas barrier layer 620, and the stiffener 700.

The gas barrier layer 620 of the semiconductor package 10F may be on the molding member 500. According to embodiments, the gas barrier layer 620 may include a first portion 621 covering the upper surface of the molding member 500 and a second portion 622 covering the side surface of the molding member 500.

The second portion 622 of the gas barrier layer 620 may extend over the side surface of the molding member 500 and a portion the side surface of the second package substrate 200. The second portion 622 may be formed to cover the portion of the side surface of the second package substrate 200 and not to overlap the substrate under-fill material layer 220. According to some embodiments, the gas barrier layer 620 may be formed after performing half sawing on the second package substrate 200 on which the first semiconductor chip 300, the second semiconductor chip 400, and the molding member 500 are formed. Therefore, the second portion 622 of the gas barrier layer 620 may be formed up to the portion of the side surface of the second package substrate 200, that is, a portion cut after a half sawing process.

Referring to FIG. 8, the semiconductor package 10G according to some embodiments may include the first package substrate 100, the second package substrate 200, the first semiconductor chip 300, the second semiconductor chip 400, the molding member 500, a gas barrier layer 630, and the stiffener 700.

The gas barrier layer 630 of the semiconductor package 10G may be on the molding member 500. According to embodiments, the gas barrier layer 630 may include a first portion 631 covering the upper surface of the molding member 500, a second portion 632 covering the side surface of the molding member 500 and a third portion 633 covering the upper surface of the first package substrate 100.

The first portion 631 of the gas barrier layer 630 may extend in the horizontal directions (the X direction and/or the Y direction) over the upper surface of the molding member 500, the upper surface of the first semiconductor chip 300, and the upper surface of the second semiconductor chip 400. The second portion 632 of the gas barrier layer 630 may extend over the side surface of the molding member 500 and the side surface of the second package substrate 200. The second portion 632 may be formed to cover at least a portion of the side surface of the second package substrate 200 and the side surface of the substrate under-fill material layer 220.

The third portion 633 of the gas barrier layer 630 may be formed on the first package substrate 100 to cover the upper surface of the first package substrate 100, the upper surface vertically not overlapping the second package substrate 200. The third portion 633 may be on the first package substrate 100, on a portion that does not vertically overlap the second package substrate 200 and the substrate under-fill material layer 220.

According to some embodiments, the gas barrier layer 630 may be formed after bonding the second package substrate 200 onto the first package substrate 100. Because the stiffener 700 is formed after forming the gas barrier layer 630 on the first package substrate 100, the stiffener 700 may be formed on the gas barrier layer 630. That is, a portion of the third portion 633 of the gas barrier layer 630 may be between the first package substrate 100 and the stiffener 700.

Referring to FIG. 9, the semiconductor package 10H according to some embodiments may include the first package substrate 100, the second package substrate 200, the first semiconductor chip 300, the second semiconductor chip 400, the molding member 500, a gas barrier layer 640, and the stiffener 700.

The gas barrier layer 640 of the semiconductor package 10H may be formed only to cover the upper surface of the molding member 500. According to some embodiments, the gas barrier layer 640 may be formed after forming the molding member 500. Because the gas barrier layer 640 does not cover the side surface of the molding member 500, the gas barrier layer 640 may restrictively prevent moisture from being absorbed into the molding member 500. In other words, because the side surface of the molding member 500 is not covered by the gas barrier layer 640, some moisture may be absorbed into the molding member 500 through the uncovered side surface.

Referring to FIG. 10, the semiconductor package 10I according to some embodiments may include the first package substrate 100, the second package substrate 200, the first semiconductor chip 300, the second semiconductor chip 400, the molding member 500, a gas barrier layer 650, and the stiffener 700.

The gas barrier layer 650 of the semiconductor package 10I may include a first portion 651 covering the upper surfaces of the first semiconductor chip 300 and the second semiconductor chip 400, a second portion 652 covering the side surfaces of the first semiconductor chip 300 and the second semiconductor chip 400, and a third portion 653 covering the upper surface of the second package substrate 200.

The first portion 651 may extend in the horizontal directions (the X direction and/or the Y direction) to cover the upper surfaces of the first semiconductor chip 300 and the second semiconductor chip 400. According to embodiments, the upper surface of the first portion 651 may not be covered by the molding member 500. For example, the upper surface of the first portion 651 may be coplanar with the upper surface of the molding member 500.

The second portion 652 may extend to cover the side surfaces of the first semiconductor chip 300 and the second portion 652. The second portion 652 may be between the side surface of the first semiconductor chip 300 and the side surface of the molding member 500 and between the side surface of the second semiconductor chip 400 and the side surface of the molding member 500. For example, the second portion 652 shown in FIG. 10 (representing an X-Z plane) may be formed by extending in the vertical direction (the Z direction) and/or the second horizontal direction (the Y direction) between the side surface of the first semiconductor chip 300 and the side surface of the molding member 500 and between the side surface of the second semiconductor chip 400 and the side surface of the molding member 500. The second portion 652 may be formed by extending along the side surfaces of the first semiconductor chip 300 and the second semiconductor chip 400 and to cover the side surfaces of the first chip under-fill material layer 320 and the second chip under-fill material layer 420.

The third portion 653 may be formed on the second package substrate 200 to cover the upper surface of the second package substrate 200, which does not vertically overlap the first semiconductor chip 300 and the second semiconductor chip 400. The third portion 653 may be on the second package substrate 200 not to vertically overlap the first semiconductor chip 300, the second semiconductor chip 400, the first chip under-fill material layer 320, and the second chip under-fill material layer 420.

According to some embodiments, the gas barrier layer 650 may be formed after the first semiconductor chip 300 and the second semiconductor chip 400 are mounted on the second package substrate 200. Each of the first semiconductor chip 300 and the second semiconductor chip 400 may be attached to the second package substrate 200, the first chip under-fill material layer 320 and the second chip under-fill material layer 420 may be formed through an under-fill process, the gas barrier layer 650 may be formed, and then the molding member 500 may be formed.

The gas barrier layer 650 may prevent moisture from being absorbed into the first chip under-fill material layer 320 and the second chip under-fill material layer 420. Since the molding member 500 is not covered by the gas barrier layer 650, some moisture may be absorbed into the molding member 500 through its uncovered surfaces.

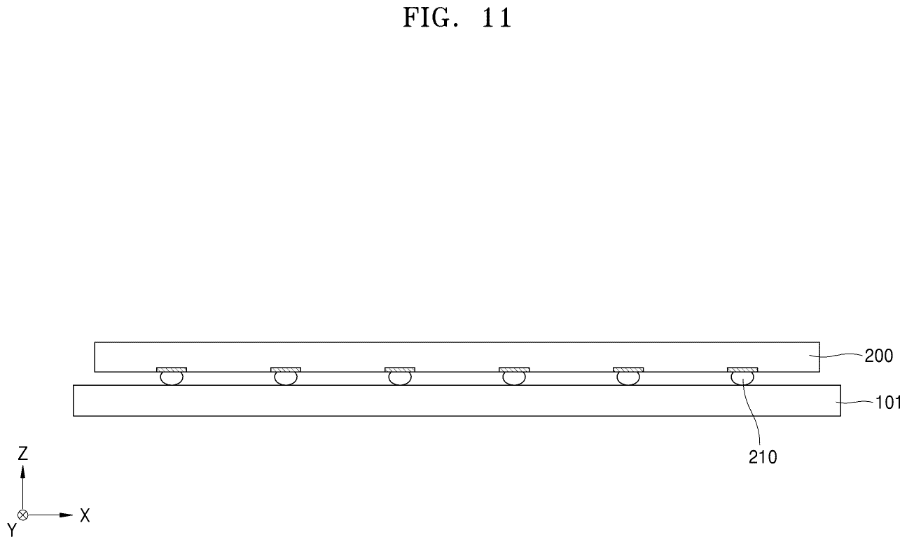

FIGS. 11 to 17 are cross-sectional views schematically illustrating, in a process order, a method of manufacturing the semiconductor package 10, according to some embodiments.

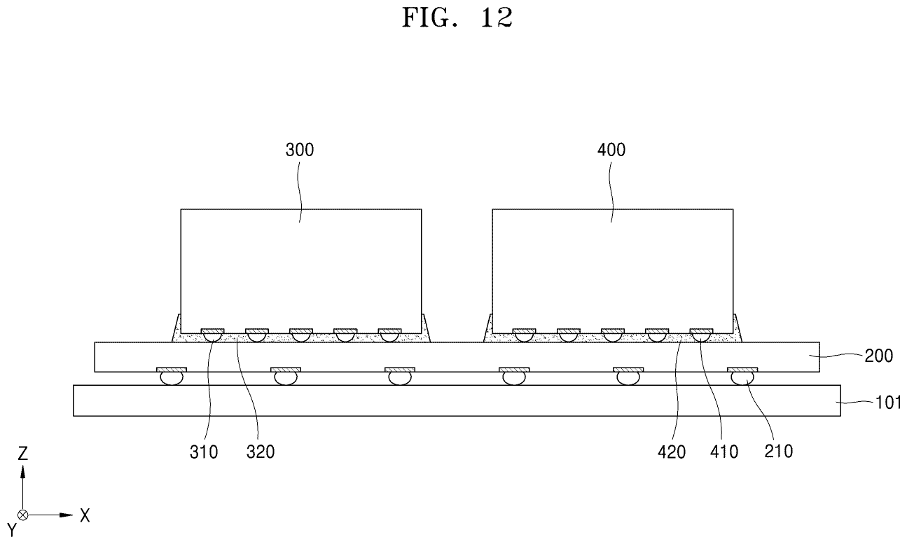

Referring to FIGS. 11 and 12, the second package substrate 200 is attached onto a carrier substrate 101, and the first semiconductor chip 300 and the second semiconductor chip 400 are on the second package substrate 200. In a process of bonding the first semiconductor chip 300 onto the second package substrate 200, the first chip under-fill material layer 320 may be formed, and in a process of bonding the second semiconductor chip 400 onto the second package substrate 200, the second chip under-fill material layer 420 may be formed.

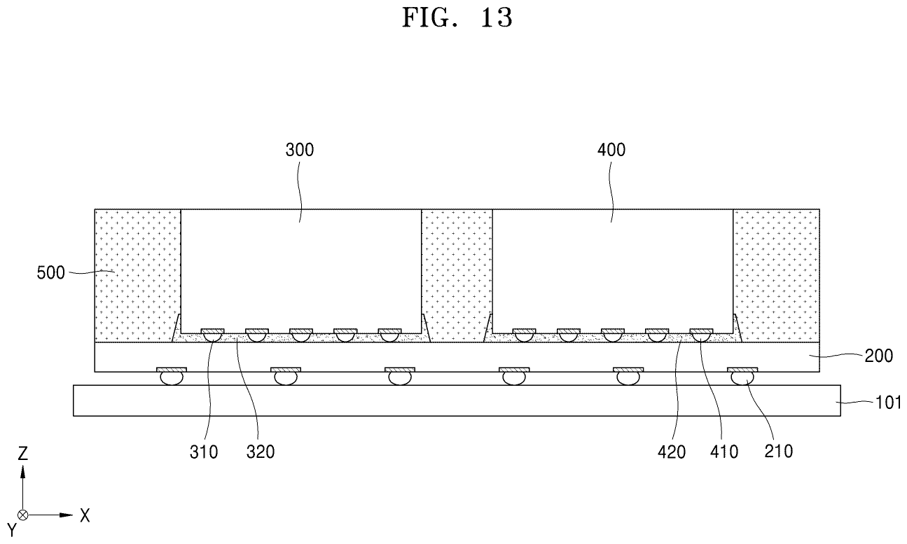

Referring to FIG. 13, in a result of FIG. 12, the molding member 500 is formed on the second package substrate 200 to surround the first semiconductor chip 300 and the second semiconductor chip 400.

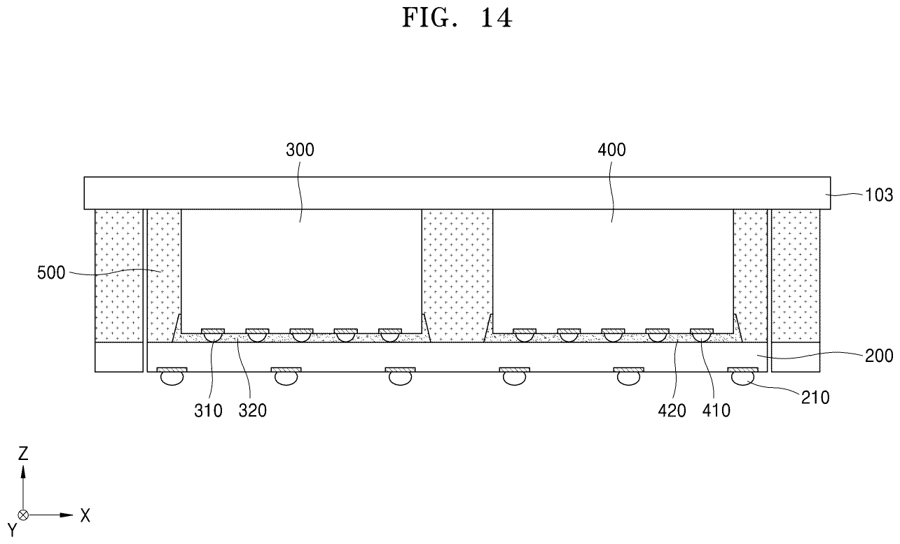

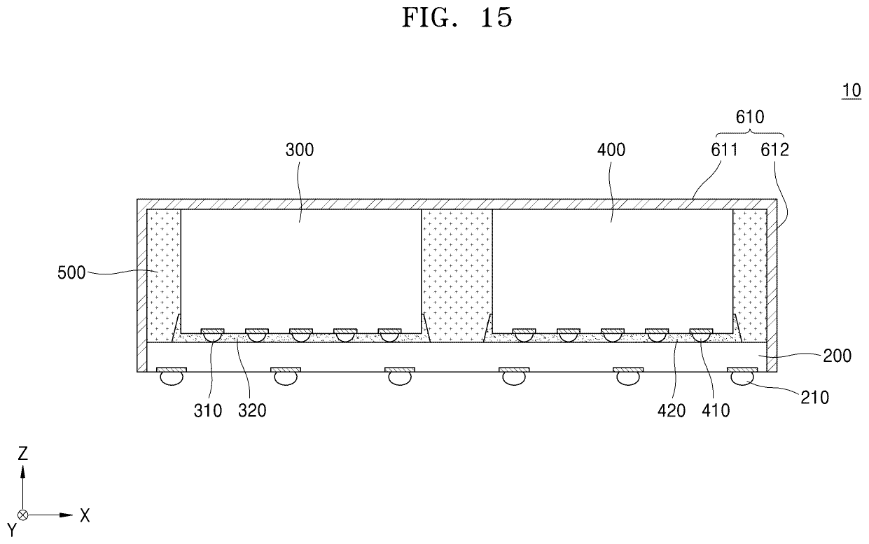

Referring to FIGS. 14 and 15, the carrier substrate 101 is separated from a result of FIG. 13, a dicing tape 103 is attached to the result of FIG. 13 from which the carrier substrate 101 is separated, and then sawing is performed thereon. After a sawing process, the dicing tape 103 may be removed and/or the gas barrier layer 610 may be formed. For example, the gas barrier layer 610 may be formed through a deposition process. The gas barrier layer 610 may include the first portion 611 covering the upper surface of the molding member 500, the upper surface of the first semiconductor chip 300, and the upper surface of the second semiconductor chip 400 and the second portion 612 covering the side surface of the molding member 500 and the side surface of the second package substrate 200.

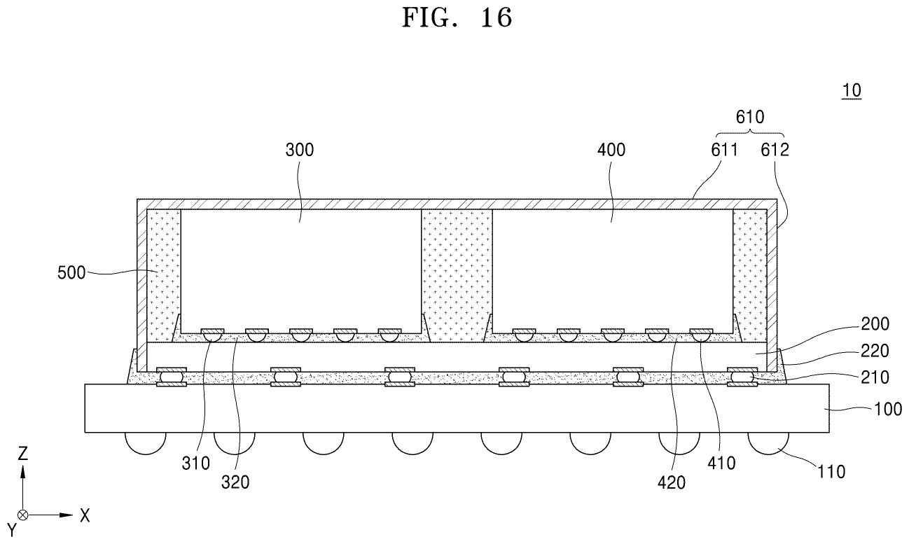

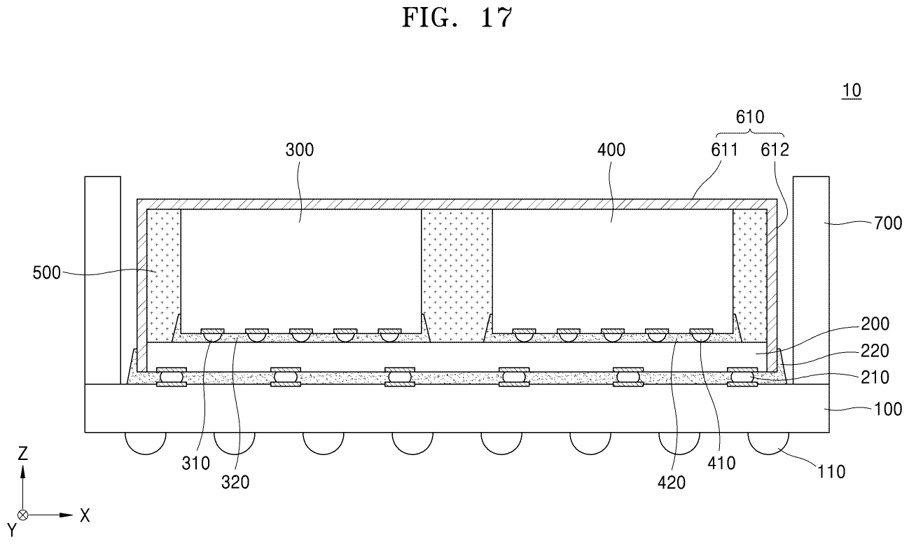

Thereafter, referring to FIGS. 16 and 17, the second package substrate 200 is attached onto the first package substrate 100. The second package substrate 200 may be electrically connected to the first package substrate 100 via the substrate connection terminals 210. The substrate under-fill material layer 220 may be formed to surround the substrate connection terminals 210 between the first package substrate 100 and the second package substrate 200.

A semiconductor package according to some embodiments may include a gas barrier layer to prevent a molding member or an under-fill material layer from absorbing moisture. In particular, the semiconductor package according to some embodiments may prevent the molding member or an under-fill material layer formed of an EMC or a polymer material from absorbing moisture. The gas barrier layer may prevent moisture absorption into the molding member or an under-fill material layer, thereby preventing swelling, which may occur when exposed to a high temperature in a subsequent process, and preventing cracks and delamination in adhesive portions of the molding member and an under-fill material layer.

While the inventive concept has been particularly shown and described with reference to embodiments thereof, it will be understood that various changes in form and details may be made therein without departing from the spirit and scope of the following claims.

What is claimed is:

1. A semiconductor package comprising:
a first package substrate;
a second package substrate on the first package substrate;
a plurality of semiconductor chips on the second package substrate;
a molding member on the second package substrate and configured to surround the plurality of semiconductor chips; and
a gas barrier layer on the molding member.

2. The semiconductor package of claim 1, wherein the gas barrier layer is configured to cover an upper surface of the molding member and upper surfaces of the plurality of semiconductor chips.

3. The semiconductor package of claim 1, wherein the gas barrier layer comprises: a first portion configured to cover an upper surface of the molding member and upper surfaces of the plurality of semiconductor chips; and a second portion configured to cover a side surface of the molding member.

4. The semiconductor package of claim 3, wherein the second portion of the gas barrier layer is configured to cover a side surface of the second package substrate.

5. The semiconductor package of claim 1, wherein the second package substrate is electrically connected to the first package substrate via substrate connection terminals, a substrate under-fill material layer configured to surround the substrate connection terminals is between the second package substrate and the first package substrate, and
the gas barrier layer comprises:
a first portion configured to cover an upper surface of the molding member and upper surfaces of the plurality of semiconductor chips;
a second portion configured to cover a side surface of the molding member, a side surface of the second package substrate, and a side surface of the substrate under-fill material layer; and
a third portion configured to cover an upper surface of the first package substrate,
wherein the upper surface of the first package substrate does not vertically overlap the second package substrate.

6. The semiconductor package of claim 1, wherein a thickness of the gas barrier layer is 5 μm or greater.

7. The semiconductor package of claim 1, wherein a water vapor transmission rate (WVTR) of the gas barrier layer is less than 1 E-3 g/m²·day.

8. The semiconductor package of claim 1, wherein the gas barrier layer comprises a ceramic layer further comprising at least one of silicon dioxide (SiO₂), silicon nitride (SiN), silicon oxide (SiOₓ), alumina (Al₂O₃), aluminum nitride (AlN), titanium dioxide (TiO₂), zinc oxide (ZnO), and titanium nitride (TiN).

9. The semiconductor package of claim 1, wherein the gas barrier layer comprises a metal layer further comprising at least one of palladium (Pd), nickel (Ni), titanium (Ti), copper (Cu), gold (Au), silver (Ag), and zinc (Zn).

10. The semiconductor package of claim 1, wherein the gas barrier layer comprises a first barrier layer and a second barrier layer stacked on the first barrier layer, and the first barrier layer and the second barrier layer are formed of different materials from each other.

11. The semiconductor package of claim 1, wherein each semiconductor chip of the plurality of semiconductor chips is horizontally spaced apart from each of the other semiconductor chips of the plurality of semiconductor chips on the second package substrate, and the second package substrate is an interposer configured to electrically connect the plurality of semiconductor chips to each other.

12. The semiconductor package of claim 1, wherein each semiconductor chip of the plurality of semiconductor chips is horizontally spaced apart from each of the other semiconductor chips of the plurality of semiconductor chips on the second package substrate, the second package substrate is a redistribution substrate, and the redistribution substrate comprises a silicon bridge configured to electrically connect the plurality of semiconductor chips to each other.

13. The semiconductor package of claim 1, wherein the second package substrate comprises a redistribution insulating layer and a redistribution pattern inside the redistribution insulating layer.

14. The semiconductor package of claim 1, wherein the plurality of semiconductor chips comprises an upper semiconductor chip and a lower semiconductor chip, which are vertically stacked.

15. A semiconductor package comprising:
a first package substrate;
a second package substrate on the first package substrate and electrically connected to the first package substrate via substrate connection terminals;
a substrate under-fill material layer between the second package substrate and the first package substrate and configured to surround the substrate connection terminals;
a plurality of semiconductor chips horizontally spaced apart from each other on the second package substrate;
a molding member on the second package substrate and configured to surround the plurality of semiconductor chips;
a gas barrier layer comprising a first portion configured to cover an upper surface of the molding member and upper surfaces of the plurality of semiconductor chips, a second portion configured to cover a side surface of the molding member, a side surface of the second package substrate, and a side surface of the substrate under-fill material layer, and a third portion configured to cover an upper surface of the first package substrate, wherein the upper surface of the first package substrate does not vertically overlap the second package substrate; and
a stiffener configured to extend in a vertical direction of the first package substrate along an edge of the first package substrate and on the third portion of the gas barrier layer.

16. A semiconductor package comprising:
a package substrate;
at least one semiconductor chip on the package substrate;
a molding member on the package substrate and configured to surround the at least one semiconductor chip; and
a gas barrier layer between the package substrate and the molding member and between the at least one semiconductor chip and the molding member.

17. The semiconductor package of claim 16, wherein a thickness of the gas barrier layer is 5 μm or greater.

18. The semiconductor package of claim 17, wherein a water vapor transmission rate (WVTR) of the gas barrier layer is less than 1 E-3 g/m²·day.

19. The semiconductor package of claim 16, wherein the gas barrier layer comprises a ceramic layer further comprising at least one of silicon dioxide (SiO₂), silicon nitride (SiN), silicon oxide (SiOₓ), alumina (Al₂O₃), aluminum nitride (AlN), titanium dioxide (TiO₂), zinc oxide (ZnO), and titanium nitride (TiN) or a metal layer further comprising at least one of palladium (Pd), nickel (Ni), titanium (Ti), copper (Cu), gold (Au), silver (Ag), and zinc (Zn).

20. The semiconductor package of claim 16, wherein the gas barrier layer comprises a first barrier layer and a second barrier layer stacked on the first barrier layer, and the first barrier layer and the second barrier layer are formed of different materials from each other.
